(19) United States
(12) Patent Application Publication
(10) Pub. No.: US 2026/0323861 A1
(43) Pub. Date: Oct. 15, 2026

(54) ELECTRONIC DEVICE AND EXPANSION MODULE

(71) Applicants: INVENTEC (PUDONG) TECHNOLOGY CORPORATION, Shanghai (CN); INVENTEC CORPORATION, Taipei City (TW)

(72) Inventor: Chang-Hsin CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/468,125

(22) Filed: Feb. 3, 2026

Related U.S. Application Data
(60) Provisional application No. 63/768,321, filed on Mar. 7, 2025.

(30) Foreign Application Priority Data
May 15, 2025 (CN) 202510628009.5

(51) Int. Cl. H05K 7/14

(52) U.S. Cl. CPC H05K 7/1489; H05K 7/1491

(57) ABSTRACT

An electronic device includes a chassis and an expansion module. The chassis includes an electronic component region, a cable region and a vertical wall. The cable region is located between the electronic component region and the vertical wall. The expansion module is disposed in the cable region and includes a frame and a circuit board. The frame is fixed to the vertical wall and includes a support portion, a first limiting portion, a second limiting portion and a plurality of cable-organizing structures. The first limiting portion, the second limiting portion and the support portion together form an accommodation space, and the cable-organizing structures protrudes from a second surface of the support portion to form a cable-organizing channel with the support portion. The accommodation space and the cable-organizing channel are located at two opposite sides of the frame. The circuit board is disposed in the accommodation space of the frame.

### CROSS-REFERENCE TO RELATED APPLICATIONS

This non-provisional application claims priority under 35 U.S.C. § 119(a) on Provisional Application No(s). 63/768,321 filed in U.S.A. on Mar. 7th, 2025, and Patent Application No(s). 202510628009.5filed in China on May 15th, 2025, the entire contents of which are hereby incorporated by reference.

### BACKGROUND OF THE INVENTION

### Technical Field of the Invention

The invention relates to an electronic device and an expansion module.

### DESCRIPTION OF THE RELATED ART

With the advancement and development of technology, electronic devices are currently equipped with an increasing number of electronic modules, resulting in progressively enhanced functionalities. However, the internal space of electronic devices is limited, which forces the electronic modules to be installed in regions that accommodate internal cables. Because the cables in such regions are typically arranged in a disorderly manner, assembly and disassembly of the electronic modules become difficult. In view of this, how to address the aforementioned issue is one of the topics in this field.

### SUMMARY OF THE INVENTION

The invention provides an electronic device and an expansion module that allow electronic modules to be easily assembled and disassembled in a cable region inside the electronic device.

One embodiment of the invention provides an electronic device. The electronic device includes a chassis and an expansion module. The chassis includes an electronic component region, a cable region and a vertical wall, and the cable region is located between the electronic component region and the vertical wall. The expansion module is disposed in the cable region of the chassis and includes a frame and a circuit board. The frame is fixed to the vertical wall and includes a support portion, a first limiting portion, a second limiting portion and a plurality of cable-organizing structures. The first limiting portion, the second limiting portion and the support portion together form an accommodation space, and the cable-organizing structures protrudes from a second surface of the support portion to form a cable-organizing channel with the support portion. The accommodation space and the cable-organizing channel are located at two opposite sides of the frame. The circuit board is disposed in the accommodation space of the frame.

Another embodiment of the invention provides an expansion module configured to be installed between a vertical wall and an electronic component region of a chassis. The expansion module includes a frame and a circuit board. The frame is configured to be fixed to the vertical wall and includes a support portion, a first limiting portion, a second limiting portion and a plurality of cable-organizing structures. The first limiting portion, the second limiting portion and the support portion together form an accommodation space, and the cable-organizing structures protrudes from a second surface of the support portion to form a cable-organizing channel with the support portion. The accommodation space and the cable-organizing channel are located at two opposite sides of the frame. The circuit board is disposed in the accommodation space of the frame.

According to the electronic device and the expansion module as disclosed in the above embodiments, the frame of the expansion module includes the cable-organizing channel and the accommodation space, the accommodation space and the cable-organizing channel are located at two opposite sides of the frame, and the circuit board is disposed in the accommodation space of the frame. By the aforementioned configuration, even when the expansion module is installed in the cable region between the electronic component region and the vertical wall, cables in the cable region can be organized in the cable-organizing channel of the frame. In this way, interference of the cables with assembly or disassembly of the expansion module can be avoided.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a partial perspective view of an electronic device according to one embodiment of the invention;

FIG. 2 is an exploded view of the electronic device in FIG. 1;

FIG. 3 is another partial perspective view of the electronic device in FIG. 1;

FIG. 4 is a partial cross-sectional view of the electronic device in FIG. 1; and

FIG. 5 is a perspective view of an expansion module in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

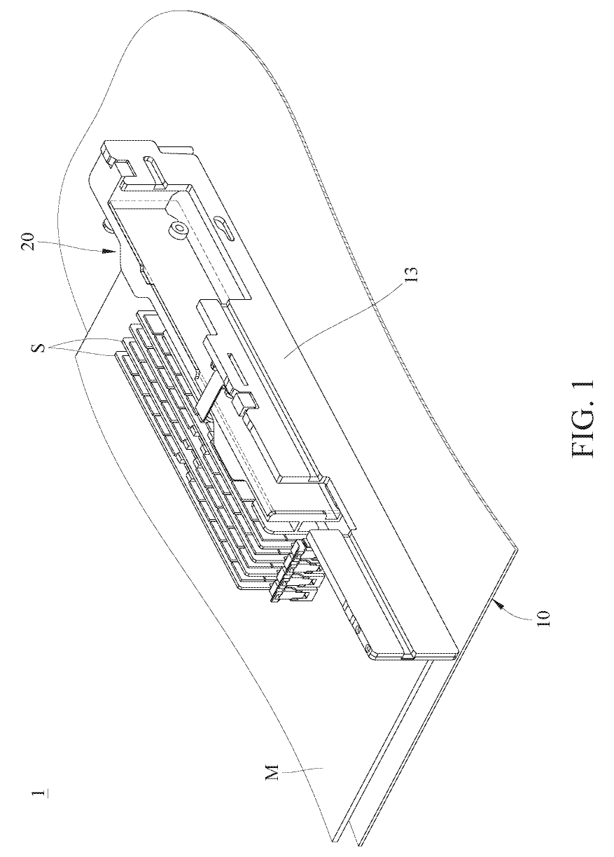

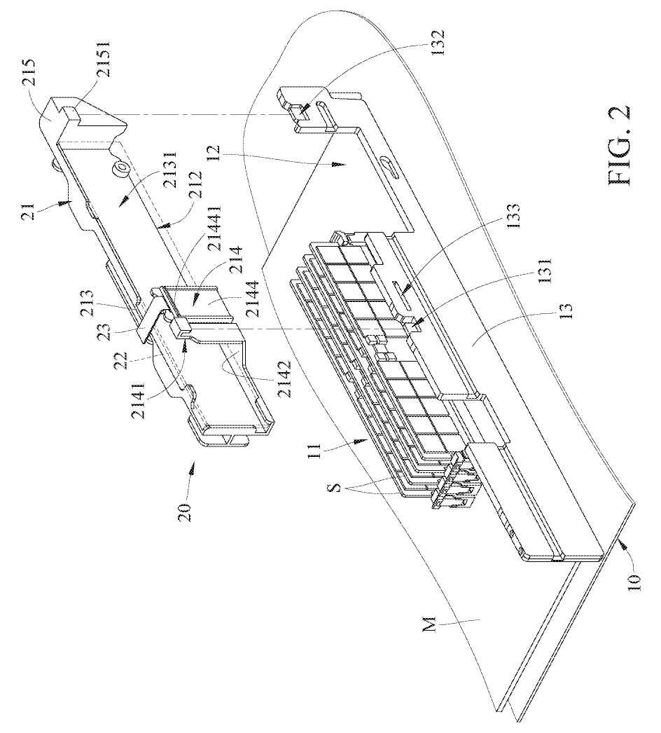

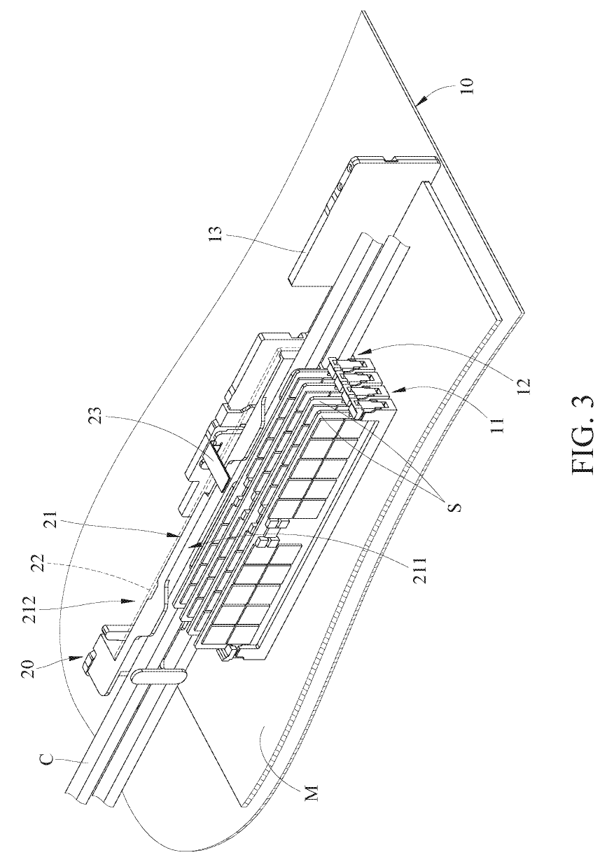

Referring to FIGS. 1 and 2,1, is a partial perspective view of an electronic device 1 according to one embodiment of the invention, FIG. 2 is an exploded view of the electronic device 1 in FIGS. 1, and 3, is another partial perspective view of the electronic device 1 in FIG. 1.

The electronic device 1 includes a chassis 10 and an expansion module 20. The chassis 10 includes an electronic component region 11, a cable region 12 and a vertical wall 13. The electronic component region 11 is, for example, configured to accommodate a data storage S, where the data storage S is inserted into a motherboard M inside the chassis 10. The cable region 12 is located between the electronic component region 11 and the vertical wall 13, and the cable region 12 is configured for allowing a plurality of cables C inside the electronic device 1 to pass therethrough. The expansion module 20 is, for example, a baseboard management module. The expansion module 20 includes a frame 21 and a circuit board 22. The frame 21 is fixed to the vertical wall 13.

In one embodiment, the frame 21 may include a support portion 213, a first limiting portion 214 and a second limiting portion 215. The first limiting portion 214 and the second limiting portion 215 are connected to a first surface 2131 of the support portion 213 and are spaced apart from each other. The first limiting portion 214, the second limiting portion 215 and the support portion 213 together form an accommodation space 212. The circuit board 22 is disposed in the accommodation space 212 of the frame 21 and is inserted into the motherboard M disposed in the chassis 10. The support portion 213 is parallel to the vertical wall 13, and the first limiting portion 214 and the second limiting portion 215 are fixed to the vertical wall 13.

In one embodiment, the vertical wall 13 may include a first positioning recess 131 and a second positioning recess 132 that are spaced apart from each other. The first limiting portion 214 may include a positioning hook 2141, and the second limiting portion 215 may include a positioning protrusion 2151. The positioning hook 2141 and the positioning protrusion 2151 are respectively and detachably positioned in the first positioning recess 131 and the second positioning recess 132. By the cooperation of the positioning hook 2141 and the positioning protrusion 2151 with the first positioning recess 131 and the second positioning recess 132, the expansion module 20 can be positioned at a desired installation location during installation in the cable region 12, thereby restricting displacement of the expansion module 20 in a horizontal direction.

In one embodiment, the vertical wall 13 may further include an engagement hole 133. The first limiting portion 214 may include a connection part 2142 and an elastic part 2144. The positioning hook 2141 and the elastic part 2144 are connected to the support portion 213 via the connection part 2142 and are spaced apart from each other, and the positioning hook 2141 and the elastic part 2144 are partially parallel to the support portion 213. That is, the positioning hook 2141 and the elastic part 2144 form a U-shaped structure with the support portion 213 via the connection part 2142. The elastic part 2144 may include an engagement block 21441, and the engagement block 21441 is detachably engaged with the engagement hole 133 of the vertical wall 13. By the engagement block 21441 of the elastic part 2144 engaging the engagement hole 133 of the vertical wall 13, a user may be informed, through the snapping sound generated when the engagement block 21441 snaps into the engagement hole 133, that the expansion module 20 has been installed in place during installation in the cable region 12, and displacement of the expansion module 20 in a vertical direction is restricted.

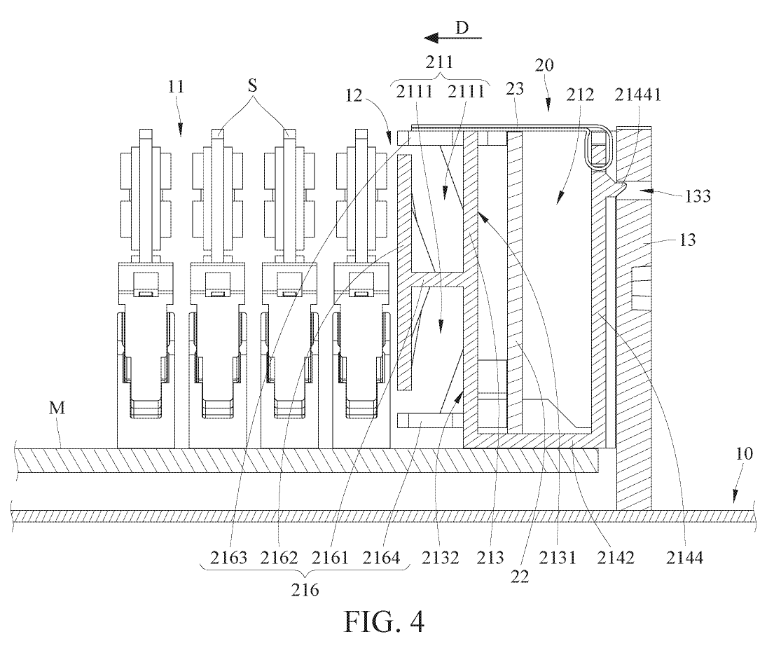

Then, referring to FIG. 4, FIG. 4 is a partial cross-sectional view of the electronic device 1 in FIG. 1.

In one embodiment, the expansion module 20 may further include an operating component 23. The operating component 23 is, for example, a pull tab, and is connected to the elastic part 2144. By pulling the operating component 23 in a direction D away from the vertical wall 13, the engagement block 21441 of the elastic part 2144 can be disengaged from the engagement hole 133 of the vertical wall 13. In this way, the expansion module 20 can be detached from the chassis 10.

In the above embodiment, through the cooperation of the positioning hook 2141 and the positioning protrusion 2151 with the first positioning recess 131 and the second positioning recess 132, the cooperation of the engagement block 21441 of the elastic part 2144 with the engagement hole 133 of the vertical wall 13, and the design of the operating component 23, the expansion module 20 can be assembled and disassembled in the chassis 10 with a toolless manner. It should be noted that the aforementioned installation structure and components for toolless installation are optional. In other embodiments, the expansion module may be installed on the chassis using tools. For example, the frame of the expansion module may be fixed to the vertical wall with screws, and assembly or disassembly of the expansion module requires the use of a screwdriver.

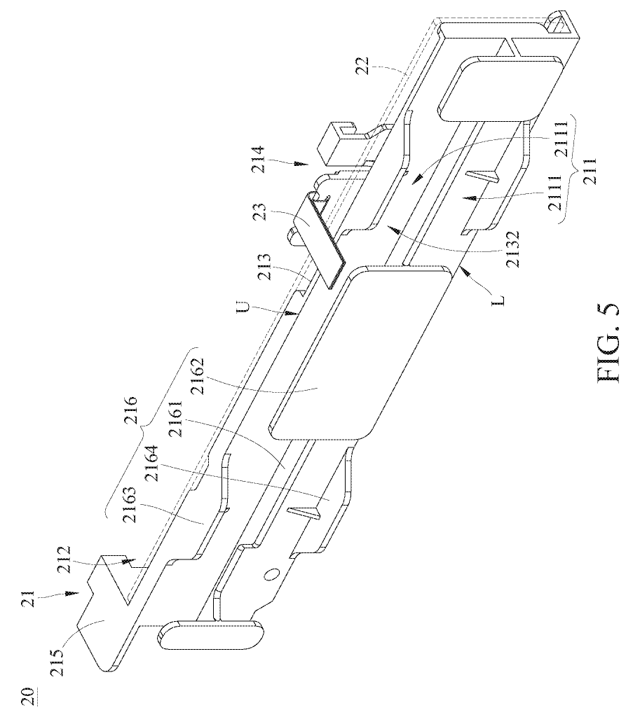

Then, referring to FIGS. 4 and 5,5, is a perspective view of the expansion module 20 in FIG. 1.

In one embodiment, the frame 21 may further include a plurality of cable- organizing structures 216, which protrude from a second surface 2132 of the support portion 213 and together form a cable-organizing channel 211. Referring also to FIG. 3, the cable-organizing channel 211 is configured to organize the cables C passing through the cable region 12. The accommodation space 212 and the cable-organizing channel 211 are located at two opposite sides of the frame 21.

In the above embodiment, the frame 21 of the expansion module 20 includes the cable-organizing channel 211 and the accommodation space 212, the accommodation space 212 and the cable-organizing channel 211 are located at two opposite sides of the frame 21, and the circuit board 22 is disposed in the accommodation space 212 of the frame 21. By the aforementioned configuration, even when the expansion module 20 is installed in the cable region 12 between the electronic component region 11 and the vertical wall 13, the cables C in the cable region 12 can be organized in the cable-organizing channel 211 of the frame 21. In this way, interference of the cables C with assembly or disassembly of the expansion module 20 can be avoided, the use of cable ties can be reduced, and the cables C are prevented from squeezing the data storage S.

In one embodiment, the cable-organizing structures 216 include a partition rib 2161 and at least one limiting wall 2162. The partition rib 2161 is spaced apart from an upper edge U and a lower edge L of the second surface 2132 of the support portion 213. The limiting wall 2162 is connected to the partition rib 2161, and is parallel to the second surface 2132 of the support portion 213. The limiting wall 2162 extends toward the upper edge U and the lower edge L of the support portion 213, and divides the cable-organizing channel 211 into two sub-channels 2111. In this way, the cables C in the cable region 12 (as shown in FIG. 3) can be arranged in layers through the two sub-channels 2111.

In one embodiment, the number of limiting walls 2162 may be multiple. The limiting walls 2162 are separately connected to the partition rib 2161.

In one embodiment, the cable-organizing structures 216 may further include at least one first limiting rib 2163 and at least one second limiting rib 2164. The first limiting rib 2163 is located at the upper edge U of the support portion 213 and is arranged in an alternating manner with the limiting wall 2162. The second limiting rib 2164 is located at the lower edge L of the support portion 213 and is arranged in an alternating manner with the limiting wall 2162. In one embodiment, the numbers of the first limiting rib 2163 and the second limiting rib 2164 may each be multiple.

It should be noted that the structure of the frame 21 forming the accommodation space 212 is not limited to the aforementioned configuration and may be adjusted as desired according to requirements.

According to the electronic device and the expansion module as disclosed in the above embodiment, the frame of the expansion module includes the cable-organizing channel and the accommodation space, the accommodation space and the cable-organizing channel are located at two opposite sides of the frame, and the circuit board is disposed in the accommodation space of the frame. By the aforementioned configuration, even when the expansion module is installed in the cable region between the electronic component region and the vertical wall, the cables in the cable region can be organized in the cable-organizing channel of the frame. In this way, interference of the cables with assembly or disassembly of the expansion module can be avoided, the use of cable ties can be reduced, and the cables are prevented from squeezing the data storage.

In addition, through the cooperation of the positioning hook and the positioning protrusion with the first positioning recess and the second positioning recess, the cooperation of the engagement block of the elastic part 2144 with the engagement hole of the vertical wall, and the design of the operating component, the expansion module can be assembled and disassembled in the chassis with a toolless manner.

The electronic device and the expansion module disclosed herein may be installed in a server. The server may be used for Artificial Intelligence (AI) computing, edge computing, or may serve as a 5G server, a cloud server, or a vehicle networking server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic device, comprising:
a chassis, comprising an electronic component region, a cable region and a vertical wall, wherein the cable region is located between the electronic component region and the vertical wall; and
an expansion module, disposed in the cable region of the chassis and comprising:
a frame, fixed to the vertical wall and comprising a support portion, a first limiting portion, a second limiting portion and a plurality of cable-organizing structures, wherein the first limiting portion, the second limiting portion and the support portion together form an accommodation space, the plurality of cable-organizing structures protrudes from a second surface of the support portion to form a cable-organizing channel with the support portion, the accommodation space and the cable-organizing channel are located at two opposite sides of the frame; and
a circuit board, disposed in the accommodation space of the frame.

2. The electronic device according to claim 1, wherein the first limiting portion and the second limiting portion are connected to a first surface of the support portion and are spaced from each other, the support portion is parallel to the vertical wall, and the first limiting portion and the second limiting portion are fixed to the vertical wall.

3. The electronic device according to claim 2, wherein the vertical wall comprises a first positioning recess and a second positioning recess spaced apart from each other, the first limiting portion comprises a positioning hook, the second limiting portion comprises a positioning protrusion, the positioning hook and the positioning protrusion are respectively detachably positioned in the first positioning recess and the second positioning recess.

4. The electronic device according to claim 3, wherein the vertical wall further comprises an engagement hole, the first limiting portion further comprises a connection part and an elastic part, the positioning hook and the elastic part are connected to the support portion via the connection part and are spaced apart from each other, the positioning hook and the elastic part are partially parallel to the support portion, the elastic part comprises an engagement block, and the engagement block is detachably engaged with the engagement hole of the vertical wall.

5. The electronic device according to claim 4, wherein the expansion module further comprises an operating component, and the operating component is connected to the elastic part.

6. The electronic device according to claim 1, wherein the plurality of cable-organizing structures comprise a partition rib and a limiting wall, the partition rib is spaced apart from an upper edge and a lower edge of the second surface of the support portion, the limiting wall is connected to the partition rib, the limiting wall is parallel to the second surface of the support portion, and the limiting wall extends toward the upper edge and the lower edge of the support portion and divides the cable-organizing channel into two sub-channels.

7. The electronic device according to claim 6, wherein the cable-organizing structures further comprise a first limiting rib and a second limiting rib, the first limiting rib is located at the upper edge of the support portion and is arranged in an alternating manner with the limiting wall, and the second limiting rib is located at the lower edge of the support portion and is arranged in an alternating manner with the limiting wall.

8. An expansion module, configured to be installed between a vertical wall and an electronic component region of a chassis, the expansion module comprising:
a frame, configured to be fixed to the vertical wall and comprising a support portion, a first limiting portion, a second limiting portion and a plurality of cable-organizing structures, wherein the first limiting portion, the second limiting portion and the support portion together form an accommodation space, the plurality of cable-organizing structures protrudes from a second surface of the support portion to form a cable-organizing channel with the support portion, the accommodation space and the cable-organizing channel are located at two opposite sides of the frame; and
a circuit board, disposed in the accommodation space of the frame.

9. The expansion module according to claim 8, wherein the first limiting portion and the second limiting portion are connected to a first surface of the support portion and are spaced from each other, the support portion is parallel to the vertical wall, and the first limiting portion and the second limiting portion are fixed to the vertical wall.

10. The expansion module according to claim 8, wherein the plurality of cable-organizing structures comprise a partition rib and a limiting wall, the partition rib is spaced apart from an upper edge and a lower edge of the second surface of the support portion, the limiting wall is connected to the partition rib, the limiting wall is parallel to the second surface of the support portion, and the limiting wall extends toward the upper edge and the lower edge of the support portion and divides the cable-organizing channel into two sub-channels.
